(19) United States
(12) Patent Application Publication
(10) Pub. No.: US 2016/0118956 A1
(43) Pub. Date: Apr. 28, 2016

(54) SURFACE ACOUSTIC WAVE RESONATOR AND SURFACE ACOUSTIC WAVE FILTER DEVICE

(71) Applicant: Murata Manufacturing Co., Ltd., Nagaokakyo-shi (JP)

(72) Inventors: Takashi KIHARA, Nagaokakyo-shi (JP); Kenichi UESAKA, Nagaokakyo-shi (JP); Ryo NAKAGAWA, Nagaokakyo-shi (JP)

(21) Appl. No.: 14/985,589

(22) Filed: Dec. 31, 2015

Related U.S. Application Data
(63) Continuation of application No. PCT/JP2014/066867, filed on Jun. 25, 2014.

(30) Foreign Application Priority Data
Jul. 2, 2013 (JP) 2013-138759

(51) Int. Cl. H03H 9/25; H03H 9/64; H01L 41/047; H03H 9/205

(52) U.S. Cl. CPC H03H 9/25; H03H 9/205; H03H 9/64; H01L 41/047

(57) ABSTRACT

In a surface acoustic wave resonator, a first IDT electrode defining a first IDT and a second IDT electrode defining a second IDT are located on a first principal surface of a piezoelectric substrate. A direction of an electric field applied to the first IDT electrode and a direction of an electric field applied to the second IDT electrode are opposite to each other with respect to a direction of a projected axis resulting from projecting a c-axis of the piezoelectric substrate to the first principal surface of the piezoelectric substrate.

### BACKGROUND OF THE INVENTION

1. Field of the Invention

The present invention relates to a surface acoustic wave resonator including a plurality of IDTs connected to each other, and to a surface acoustic wave filter device including the surface acoustic wave resonator.

2. Description of the Related Art

Various bandpass filters are employed in, e.g., duplexers for cellular phones. Japanese Unexamined Patent Application Publication No. 2008-085989 discloses a device in which first and second resonators, each being a BAW resonator, are connected in series. In the BAW resonator, a pair of electrodes is arranged in the direction of a c-axis of a piezoelectric material or the direction of a polarization axis thereof with the piezoelectric material interposed between the electrodes. In Japanese Unexamined Patent Application Publication No. 2008-085989, the electrodes present in the same direction with respect to the c-axis or the polarization axis are held at the same potential in the first and second resonators. As a result, second harmonic distortion is suppressed.

On the other hand, Japanese Unexamined Patent Application Publication No. 2007-336479 discloses a duplexer including a surface acoustic wave device in which a plurality of IDT electrodes is formed on a piezoelectric substrate. In the disclosed duplexer, a parallel resonance circuit is connected to an antenna terminal to prevent a particular frequency from passing therethrough. Thus, input of a signal having the particular frequency, e.g., a signal attributable to second harmonic distortion, is prevented with resonance characteristics of the parallel resonance circuit.

In cellular phones and so on, degradation of reception characteristics attributable to a second harmonic distortion signal becomes a problem with the progress toward practical use of a multiband system. For example, a wave having a frequency, which is twice the frequency of a transmission wave in one band, may fall within a reception range in another band. In such a case, in a duplexer including a surface acoustic wave device, a second harmonic distortion signal having a frequency twice that of the transmission wave is generated when the relevant transmission wave is output. If the second harmonic distortion signal is mixed into a reception circuit, the reception characteristics would degrade.

In the device disclosed in Japanese Unexamined Patent Application Publication No. 2008-085989 and utilizing a BAW (Bulk Acoustic Wave), the second harmonic distortion signal is suppressed with the configuration described above. However, Japanese Unexamined Patent Application Publication No. 2008-085989 discloses nothing about the second harmonic distortion signal in a device including IDT electrodes arranged on a piezoelectric substrate and utilizing a surface acoustic wave.

On the other hand, as described in Japanese Unexamined Patent Application Publication No. 2007-336479, the surface acoustic wave device uses a method of connecting the parallel resonance circuit, for example, in order to suppress input of the signal having the particular frequency. Such a method is effective when the frequency of an input distortion signal is within a particular frequency range where the input distortion signal is attenuated by the parallel resonance circuit. However, the disclosed method cannot suppress a distortion signal having a frequency outside a preset frequency range.

### SUMMARY OF THE INVENTION

Preferred embodiments of the present invention provide a surface acoustic wave resonator that effectively suppresses a distortion signal attributable to nonlinearity of acoustic vibration, such as a second harmonic distortion signal, and provide a surface acoustic wave filter device including the surface acoustic wave resonator.

The surface acoustic wave resonator according to a preferred embodiment of the present invention includes a first terminal, a second terminal, and first and second IDTs connected between the first terminal and the second terminal. In a preferred embodiment of the present invention, the surface acoustic wave resonator further includes a piezoelectric substrate and first and second IDT electrodes. The piezoelectric substrate includes a first principal surface and a second principal surface opposed to the first principal surface, and has a c-axis of which direction is inclined relative to the first principal surface and the second principal surface. The first IDT electrode is provided on the first principal surface of the piezoelectric substrate to define the first IDT. The first IDT electrode includes first and second comb-shaped electrodes. The second IDT electrode is located on the first principal surface of the piezoelectric substrate to define the second IDT. The second IDT electrode includes third and fourth comb-shaped electrodes.

In a preferred embodiment of the present invention, when looking at the first principal surface in a plan view, a direction of an electric field applied to the first IDT and a direction of an electric field applied to the second IDT are opposite to each other with respect to a direction parallel to a projected c-axis resulting from projecting the c-axis to the first principal surface of the piezoelectric substrate.

In a surface acoustic wave resonator according to one specific aspect of a preferred embodiment of the present invention, each of the first and second IDT electrodes includes a plurality of electrode fingers, and an extending direction of the projected c-axis resulting from projecting the c-axis to the first principal surface has a component parallel to a direction in which the plural electrode fingers of the first and second IDT electrodes extend.

In a surface acoustic wave resonator according to another specific aspect of a preferred embodiment of the present invention, when the c-axis is projected to the first principal surface, the extending direction of the projected c-axis is parallel to the direction in which the electrode fingers of the first and second IDT electrodes extend.

In a surface acoustic wave resonator according to still another specific aspect of a preferred embodiment of the present invention, the first IDT and the second IDT are electrically connected in parallel.

In a surface acoustic wave resonator according to still another specific aspect of a preferred embodiment of the present invention, the first IDT and the second IDT are electrically connected in series.

A surface acoustic wave resonator according to still another specific aspect of a preferred embodiment of the present invention further includes a wiring pattern that electrically connects the first IDT and the second IDT, the wiring pattern being disposed on the first principal surface of the piezoelectric substrate at a position effective to suppress acoustic coupling between surface acoustic waves generated from the first IDT and the second IDT.

A surface acoustic wave resonator according to still another specific aspect of a preferred embodiment of the present invention further includes a wiring pattern that electrically connects the first IDT and the second IDT, the wiring pattern being disposed on the first principal surface of the piezoelectric substrate between the first IDT and the second IDT.

In a surface acoustic wave resonator according to still another specific aspect of a preferred embodiment of the present invention, the first IDT and the second IDT are arranged in a state displaced from each other in a direction of an electrode-finger intersecting width of the first IDT.

A surface acoustic wave filter device according to a preferred embodiment of the present invention includes a surface acoustic wave filter section including a reverse connection circuit defined by the surface acoustic wave resonator according to another preferred embodiment of the present invention.

In a surface acoustic wave filter device according to still another aspect of a preferred embodiment of the present invention, the surface acoustic wave filter section includes a ladder filter section.

In a surface acoustic wave filter device according to still another aspect of a preferred embodiment of the present invention, the surface acoustic wave filter device includes an antenna terminal and a transmission terminal, the ladder filter section includes a series arm connecting the antenna terminal to the transmission terminal, at least two parallel arms connected to the series arm and a ground potential, a plurality of series arm resonators disposed in the series arm, and at least one parallel arm resonator provided for each of the parallel arms, one of the plural series arm resonators that is located closest to the antenna terminal is defined by one unit of the reverse connection circuit, and the parallel arm resonator arranged in one of the at least two parallel arms located closest to the antenna terminal is defined by another unit of the reverse connection circuit.

In a surface acoustic wave filter device according to still another aspect of a preferred embodiment of the present invention, the surface acoustic wave filter section includes a surface acoustic wave filter section of longitudinally coupled resonator type.

A multiplexer according to a preferred embodiment of the present invention includes a common connection terminal and a plurality of filters connected to the common connection terminal in parallel, and at least one of the plural filters is defined by the surface acoustic wave filter device according to another preferred embodiment of the present invention.

In a surface acoustic wave resonator according to a preferred embodiment of the present invention, since the direction of the electric field applied to the first IDT and the direction of the electric field applied to the second IDT are opposite to each other with respect to the direction that is parallel to the projected c-axis resulting from projecting the c-axis to the first principal surface of the piezoelectric substrate, the phase of a distortion signal in the first IDT and the phase of a distortion signal in the second IDT are opposite to each other. It is hence possible to effectively suppress a distortion signal attributable to nonlinearity of an acoustic signal, such as a second harmonic distortion signal.

The above and other elements, features, steps, characteristics and advantages of the present invention will become more apparent from the following detailed description of the preferred embodiments with reference to the attached drawings.

### BRIEF DESCRIPTION OF THE DRAWINGS

FIG. 1 is a schematic plan view of a surface acoustic wave filter device including a surface acoustic wave resonator according to a first preferred embodiment of the present invention.

FIG. 2 is a schematic side view illustrating a relation between a c-axis and a direction of an electric field in the surface acoustic wave resonator according to the first preferred embodiment of the present invention.

FIG. 3 is a perspective view illustrating one example of a relation between the c-axis of a piezoelectric substrate and a direction of excited vibration in a surface acoustic wave resonator.

FIG. 4 is a perspective view illustrating another example of the relation between the c-axis of the piezoelectric substrate and the direction of the excited vibration in a surface acoustic wave resonator.

FIG. 5 is a schematic plan view of a surface acoustic wave resonator section included in the surface acoustic wave filter device according to the first preferred embodiment of the present invention.

FIG. 6 is a graph depicting a relation between a generation frequency of second harmonic distortion and intensity of a second harmonic distortion signal in a preferred embodiment of the present invention and a comparative example.

FIG. 7 is a diagram illustrating a circuit configuration of a duplexer that defines and functions as a surface acoustic wave filter device according to a second preferred embodiment of the present invention.

FIG. 8 is a diagram illustrating a circuit configuration of a duplexer that defines and functions as a surface acoustic wave filter device according to a third preferred embodiment of the present invention.

FIG. 9 is a diagram illustrating a circuit configuration of a duplexer that defines and functions as a surface acoustic wave filter device according to a fourth preferred embodiment of the present invention.

FIG. 10 is a circuit diagram illustrating a modification of a reverse connection circuit.

FIG. 11 is a diagram illustrating a circuit configuration of a duplexer that defines and functions as a surface acoustic wave filter device according to a fifth preferred embodiment of the present invention.

FIG. 12 is a diagram illustrating a circuit configuration of a ladder filter that defines and functions as a sixth preferred embodiment of the present invention.

FIG. 13 is a diagram illustrating a circuit configuration of a ladder filter that defines and functions as a seventh preferred embodiment of the present invention.

FIG. 14 is a diagram illustrating a circuit configuration of a duplexer that defines and functions as an eighth preferred embodiment of the present invention, the duplexer including a ladder filter and a longitudinally coupled acoustic resonator-type filter.

FIG. 15 is a graph depicting results of measuring transfer characteristics in the eighth to tenth preferred embodiments of the present invention and the comparative example.

FIG. 16 is a graph depicting results of measuring second harmonic intermodulation distortions in the eighth to tenth preferred embodiments of the present invention and the comparative example.

FIG. 17 is a circuit diagram of a surface acoustic wave filter device of longitudinally coupled acoustic resonator type, which represents an eleventh preferred embodiment of the present invention.

### DETAILED DESCRIPTION OF THE PREFERRED EMBODIMENTS

The present invention will be described based on various preferred embodiments of the present invention with reference to the drawings.

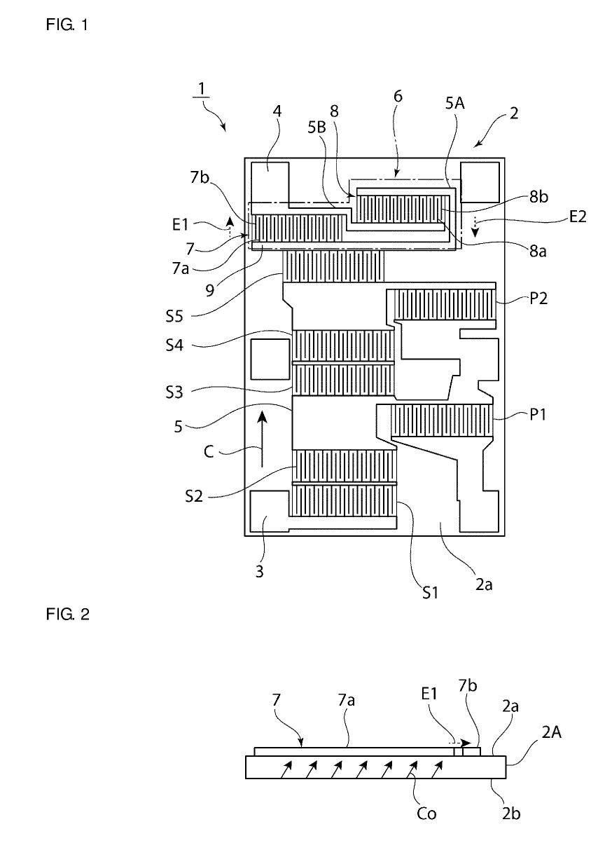

FIG. 1 is a schematic plan view of a surface acoustic wave filter device according to a first preferred embodiment of the present invention.

The surface acoustic wave filter device 1 includes a piezoelectric substrate 2. The piezoelectric substrate 2 has a composite structure in which a piezoelectric film having piezoelectricity and made of, e.g., a piezoelectric single crystal such as LiTaO₃ or LiNbO₃ is provided on a carrier in the form of, for example, a substrate made of, e.g., a piezoelectric single crystal such as LiTaO₃ or LiNbO₃, or a non-piezoelectric substrate.

An electrode structure illustrated in FIG. 1 is provided on the piezoelectric substrate 2. The electrode structure includes an input terminal 3 and an output terminal 4. A plurality of IDT electrodes defining series arm resonators S1 to S5, respectively, is connected in series between the input terminal 3 and the output terminal 4. IDT electrodes defining parallel arm resonators P1 and P2 are also provided. The series arm resonators S1 to S5 and the parallel arm resonators P1 and P2 are electrically connected through wiring patterns 5.

On the piezoelectric substrate 2, a reverse connection portion 6 defining one preferred embodiment of the present invention is provided between the series arm resonator S5 and the output terminal 4. The reverse connection portion 6 includes a first IDT electrode 7 and a second IDT electrode 8. In other words, a first IDT and a second IDT are preferably provided respectively by providing the first IDT electrode 7 and the second IDT electrode 8 on the piezoelectric substrate 2.

The first IDT electrode 7 includes first and second comb-shaped electrodes 7a and 7b including respective plural electrode fingers that are interdigitated with each other. Similarly, the second IDT electrode 8 includes third and fourth comb-shaped electrodes 8a and 8b including respective plural electrode fingers that are interdigitated with each other. In the reverse connection portion 6, a busbar 9 to which the series arm resonator S5 and the first and second IDT electrodes 7 and 8 are connected defines a first terminal, and the output terminal 4 defines a second terminal. In other words, the first IDT and the second IDT are connected between the first terminal and the second terminal. In this preferred embodiment, the first IDT electrode 7 and the second IDT electrode 8 are electrically connected in parallel.

The piezoelectric substrate 2 is made of the above-mentioned piezoelectric single crystal. The c-axis is inclined toward an upper surface of the piezoelectric substrate 2, which is a first principal surface 2a, starting from a lower surface thereof, which is a second principal surface. Furthermore, a direction of a projected c-axis resulting from projecting the c-axis to the first principal surface 2a is as shown by an arrow C. Stated in another way, when looking at the piezoelectric substrate 2 in a plan view, the c-axis is oriented in the direction denoted by the arrow C.

Here, the orientation of the c-axis may be measured by using an ordinary measurement method. More specifically, an angle of the c-axis of the piezoelectric substrate may be determined by pole figure measurement of azimuth <001> with the aid of XRD (X-ray diffraction) on an assumption that a crystal structure of the piezoelectric substrate is expressed as a hexagonal crystal structure.

This preferred embodiment is featured in that a direction of an electric field applied to the first IDT electrode 7 and a direction of an electric field applied to the second IDT electrode 8 are opposite to each other with respect to a direction parallel to the arrow C. In more detail, in the first IDT electrode 7, the first comb-shaped electrode 7a is connected to the input side, and the second comb-shaped electrode 7b is connected to the output side. More specifically, the first comb-shaped electrode 7a is connected to the busbar 9 on the input side, and the second comb-shaped electrode 7b is connected to the output terminal 4. Accordingly, an arrow E1 representing the direction of the electric field applied to the first IDT electrode 7 is oriented in the same direction as that of the arrow C.

On the other hand, in the second IDT electrode 8, the fourth comb-shaped electrode 8b is connected to the busbar 9 through a wiring pattern 5A. The third comb-shaped electrode 8a is connected to the output terminal 4 through a wiring pattern 5B. Accordingly, an arrow E2 representing the direction of the electric field applied to the second IDT electrode 8 is oriented in an opposite direction to the arrow C.

Thus, in this preferred embodiment, the first IDT electrode 7 and the second IDT electrode 8 are electrically connected in parallel through the wiring pattern 5A and the wiring pattern 5B such that, as described above, the electric fields in directions opposed to each other are applied to the first and second IDT electrodes 7 and 8. More specifically, the first comb-shaped electrode 7a of the first IDT electrode 7, the electrode 7a being positioned on the side closer to the input terminal 3, and the fourth comb-shaped electrode 8b of the second IDT electrode 8, the electrode 8b being positioned on the side closer to the output terminal 4, are electrically connected to each other through the wiring pattern 5A. Furthermore, the second comb-shaped electrode 7b of the first IDT electrode 7, the electrode 7b being positioned on the side closer to the output terminal 4, and the third comb-shaped electrode 8a, which is positioned on the side closer to the input terminal 3, are electrically connected to each other through the wiring pattern 5B. Such a configuration causes second harmonic distortion signals cancel each other between the first and second IDT electrodes 7 and 8. As a result, generation of a resultant second harmonic distortion signal is suppressed effectively. Moreover, the wiring pattern 5B is positioned in propagation directions of surface acoustic waves generated from the first IDT electrode 7 and the second IDT electrode 8, and is disposed in a region of the piezoelectric substrate 2 located between the first IDT electrode 7 and the second IDT electrode 8. Such an arrangement is effective in suppressing acoustic coupling between the first IDT electrode 7 and the second IDT electrode 8. When a propagation path A of the surface acoustic wave generated from the first IDT electrode 7 and a propagation path B of the surface acoustic wave generated from the second IDT electrode 8 overlap each other, it is preferable that the wiring pattern 5B is disposed at a position where the propagation path A and the propagation path B overlap each other, the position being positioned in a region of the piezoelectric substrate 2 located between the first IDT electrode 7 and the second IDT electrode 8. In addition, the first IDT electrode 7 and the second IDT electrode 8 are arranged while a distance is held between both the electrodes in a direction perpendicular to the propagation directions of the surface acoustic waves. Such an arrangement is also effective in suppressing acoustic coupling in a longitudinal mode between the IDT electrode 7 and the IDT electrode 8.

In practice, an input signal is applied to the surface acoustic wave filter device 1 through the input terminal 3. An output signal is output from the output terminal 4. However, a second harmonic distortion signal is generated in some cases. In those cases, an IDT positioned closest to the output terminal 4 in the ladder filter section generates the second harmonic distortion signal in a maximum magnitude. In other words, such an IDT is the IDT defining the series arm resonator S5.

In this preferred embodiment, the reverse connection portion 6 is connected between the series arm resonator S5 and the output terminal 4. With the presence of the reverse connection portion 6, the generation of the second harmonic distortion signal is suppressed effectively. The configuration of the reverse connection portion 6, which causes the second harmonic distortion signals to cancel each other, will be described in more detail below.

FIG. 2 is a schematic side view illustrating a portion of the piezoelectric substrate 2, i.e., a piezoelectric substrate portion 2A, in an extracted state. In the piezoelectric substrate portion 2A, an arrow Co represents the direction of the c-axis. Thus, the arrow Co is extends from the second principal surface 2b toward the first principal surface 2a. However, the arrow Co extends in a direction inclined relative to the first principal surface 2a. The direction of the projected c-axis resulting from projecting the direction of the c-axis to the first principal surface 2a is the same as that of the above-mentioned arrow C in FIG. 1.

In the first IDT electrode 7, the first comb-shaped electrode 7a is connected to the input side, and the second comb-shaped electrode 7b is connected to the output side. Accordingly, the direction E1 of the electric field applied to the first IDT electrode 7 is the same as the direction C of the projected axis resulting from projecting the arrow Co to the first principal surface 2a.

On the other hand, as illustrated in FIG. 1, the direction E2 of the electric field applied to the second IDT electrode 8 is opposite to the direction E1 of the electric field applied to the first IDT electrode 7. In other words, this preferred embodiment includes a reverse connection circuit in which the first IDT electrode 7 and the second IDT electrode 8 electrically connected to each other are connected such that the directions of the electric fields applied to those IDT electrodes are reversed with respect to the direction of the c-axis of the piezoelectric substrate.

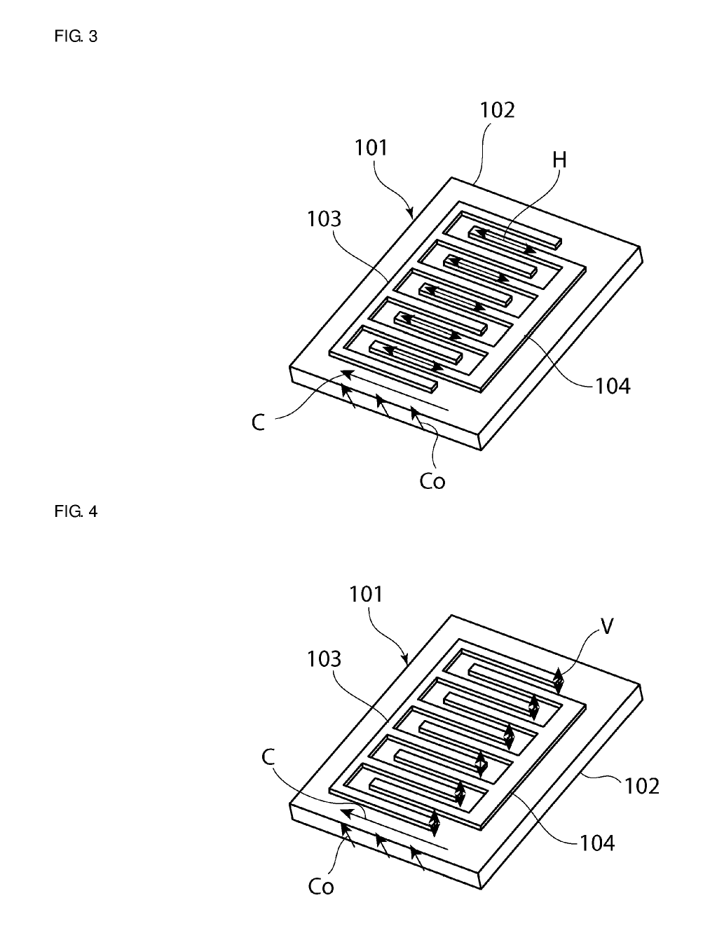

Thus, the direction of the projected c-axis has a component parallel to a direction in which the electrode fingers of the first and second IDT electrodes 7 and 8 extend. In a frequency band used for cellular phones, typical acoustic vibration components of excited surface acoustic waves have vectors represented by arrows H and V in FIGS. 3 and 4.

FIG. 3 illustrates a 1-port surface acoustic wave resonator 101. The 1-port surface acoustic wave resonator 101 includes a piezoelectric substrate 102. In the piezoelectric substrate 102, the direction of a c-axis is the same as that denoted by an arrow Co in FIG. 3, and a horizontal component of the c-axis is oriented in a direction denoted by an arrow C. Respective electrode fingers of comb-shaped electrodes 103 and 104 extend in the same direction as the extending direction of the arrow C. When the surface acoustic wave resonator 101 is operated with the comb-shaped electrode 103 being on the input side and the comb-shaped electrode 104 being on the output side, vibration components are generated in a direction denoted by an arrow H. The vibration components in the direction denoted by the arrow H have vectors in the same direction as that of the arrow C. An example of such a vibration mode is a leaky wave.

On the other hand, in a surface acoustic wave resonator 101 illustrated in FIG. 4, when electric fields are applied to first and second comb-shaped electrodes 103 and 104 in a similar manner to that in the above case, vibration components denoted by arrows V are generated. Such a vibration mode has a vector that is oriented in the same direction as a vertical component of the c-axis. An example of that vibration mode having the vibration component V is a Rayleigh wave.

In any of the vibration modes illustrated in FIGS. 3 and 4, when the c-axis is inclined relative to a direction normal to a first principal surface of the piezoelectric substrate 102, an acoustic vibration displacement becomes asymmetric with respect to the c-axis. With the asymmetry of the acoustic vibration, second harmonic distortion is generated in the surface acoustic wave resonator or the surface acoustic wave filter. The acoustic vibration is generated upon application of a voltage to the IDT electrode.

In the preferred embodiment described above, the directions of the electric fields applied to the first IDT electrode 7 and the second IDT electrode 8 are opposite to each other with respect to the direction of the horizontal component of the c-axis. Accordingly, phases of the generated second harmonic distortion signals are also reversed. As a result, in the first IDT electrode 7 and the second IDT electrode 8, it is possible to cause the second harmonic distortion signals to cancel each other, and to effectively suppress generation of a resultant second harmonic distortion signal.

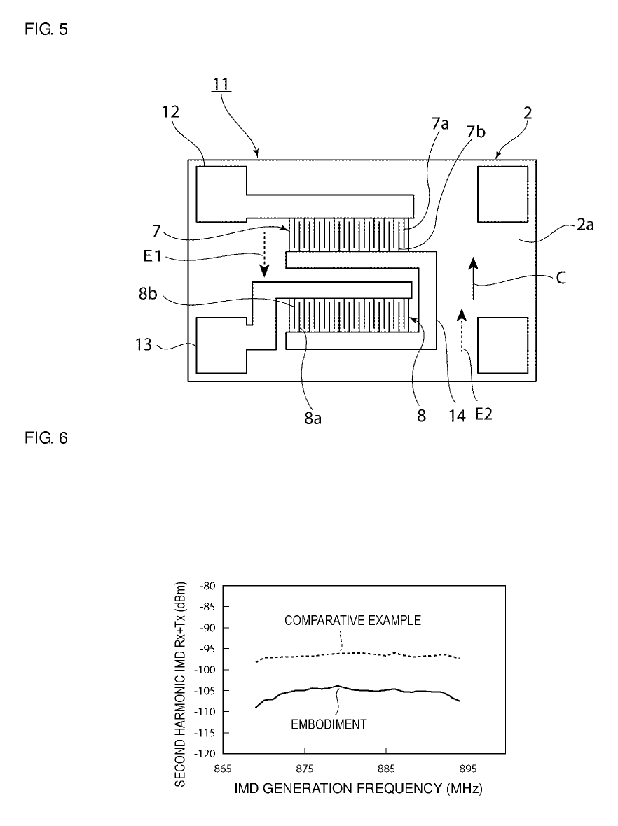

Instead of the reverse connection portion 6 described above, a reverse connection portion 11 may be used which is defined by a surface acoustic wave resonator illustrated in FIG. 5. In the reverse connection portion 11, the first and second IDT electrodes 7 and 8 are provided on the piezoelectric substrate 2. A direction of a projected axis resulting from projecting the c-axis of the piezoelectric substrate 2 to the first principal surface 2a is denoted by an arrow C. In other words, a horizontal component of the c-axis is oriented in a direction denoted by the arrow C.

On the first principal surface 2a of the piezoelectric substrate 2, the first IDT electrode 7 is connected to a first terminal 12. The first IDT electrode 7 and the second IDT electrode 8 are electrically connected in series. More specifically, the first comb-shaped electrode 7a is connected to the first terminal 12. The second comb-shaped electrode 7b is electrically connected to the third comb-shaped electrode 8a of the second IDT electrode 8 through a wiring pattern 14. The fourth comb-shaped electrode 8b is electrically connected to a second terminal 13. Thus, the first and second IDT electrodes 7 and 8 are connected in series between the first terminal 12 and the second terminal 13.

Here, a direction in which the electrode fingers of the first IDT electrode 7 and the second IDT electrode 8 extend is parallel to the direction denoted by the arrow C. Assuming that the first terminal 12 is an input terminal and the second terminal 13 is an output terminal, a direction E1 of the electric field applied to the first IDT electrode 7 is opposite to the direction denoted by the arrow C. On the other hand, a direction E2 of the electric field applied to the second IDT electrode 8 is the same as that denoted by the arrow C. Thus, the direction E2 of the applied electric field and the direction E1 of the applied electric field are opposite to each other with respect to the direction in which the arrow C extends.

It is to be noted that, as illustrated in FIG. 5, the directions E1 and E2 of the applied electric fields extend in the direction in which the pair of electrode fingers opposed to each other extend. Such a point is similarly applied to the following description related to the directions of the applied electric fields.

As described above, the first and second IDT electrodes 7 and 8 may be electrically connected in series. Also in such a case, the phase of the second harmonic distortion signal generated from the first IDT electrode 7 and the phase of the second harmonic distortion signal generated from the second IDT electrode 8 are opposite to each other. Hence the resultant second harmonic distortion signal is suppressed effectively.

As illustrated in FIGS. 1 to 5, the first IDT electrode 7 and the second IDT electrode 8 are preferably displaced from each other in a direction of an electrode-finger intersecting width of the first IDT electrode 7. With such an arrangement, the second harmonic distortion signal generated through acoustic coupling of the surface acoustic waves from the first IDT electrode 7 and the second IDT electrode 8 is suppressed more effectively. More preferably, the first and second IDT electrodes 7 and 8 are arranged at positions displaced to such an extent as not overlapping each other in the direction of the electrode-finger intersecting width. Thus, it is desirable that, as illustrated in FIG. 5, the first and second IDT electrodes 7 and 8 do not overlap each other on the piezoelectric substrate 2 in the direction of the electrode-finger intersecting width. The term “electrode-finger intersecting width” implies a size of a region where adjacent electrode fingers connected to different potentials overlap each other in the propagation direction of the surface acoustic waves, the size being measured in the direction in which the electrode fingers extend. Accordingly, the direction of the electrode-finger intersecting width is the direction in which the electrode-finger intersecting width extends, i.e., the direction in which the electrode fingers extend. A busbar connected to the second comb-shaped electrode 7b and a busbar connected to the fourth comb-shaped electrode 8b are not used in common, and are arranged on the piezoelectric substrate 2 at positions spaced from each other with a gap left between both the busbars. Such an arrangement is effective in suppressing acoustic coupling in a transverse mode between the first IDT electrode 7 and the second IDT electrode 8.

A magnitude of the second harmonic distortion signal generated in a balanced duplexer including, as a transmission filter, the surface acoustic wave filter device including the reverse connection portion 6 according to the above-described preferred embodiment was measured. For comparison, a magnitude of the second harmonic distortion signal generated in a balanced duplexer, defined in the same configuration as that of the above duplexer except for not including the reverse connection portion 6, was also measured. FIG. 6 plots the measured results.

A generation frequency of intermodulation distortion (IMD) denoted by a horizontal axis of FIG. 6 represents a generation frequency of the second harmonic distortion signal, and second harmonic IMD Rx+Tx denoted by a vertical axis represents the magnitude of the generated distortion signal, i.e., the intensity of the second harmonic distortion signal that has entered the receiving side from the transmitting side.

As seen from FIG. 6, in a comparative example, the intensity of the second harmonic distortion signal is about −96 dBm. On the other hand, in the duplexer including the reverse connection portion 6, the intensity of the second harmonic distortion signal is much smaller than that in the comparative example, i.e., about −105 dBm. It is hence understood that the second harmonic distortion signal is suppressed by the reverse connection portion 6.

In a duplexer, particularly, the second harmonic distortion signal is more likely to be generated, as described later, at a combined end that defines an end portion of the duplexer on the side where a transmission filter and a reception filter are connected to each other. In this preferred embodiment, as illustrated in FIG. 1, the reverse connection portion 6 is disposed on the output terminal side, i.e., at the combined end on the side opposite to a transmission terminal. Therefore, the generation of the second harmonic distortion signal is suppressed more effectively.

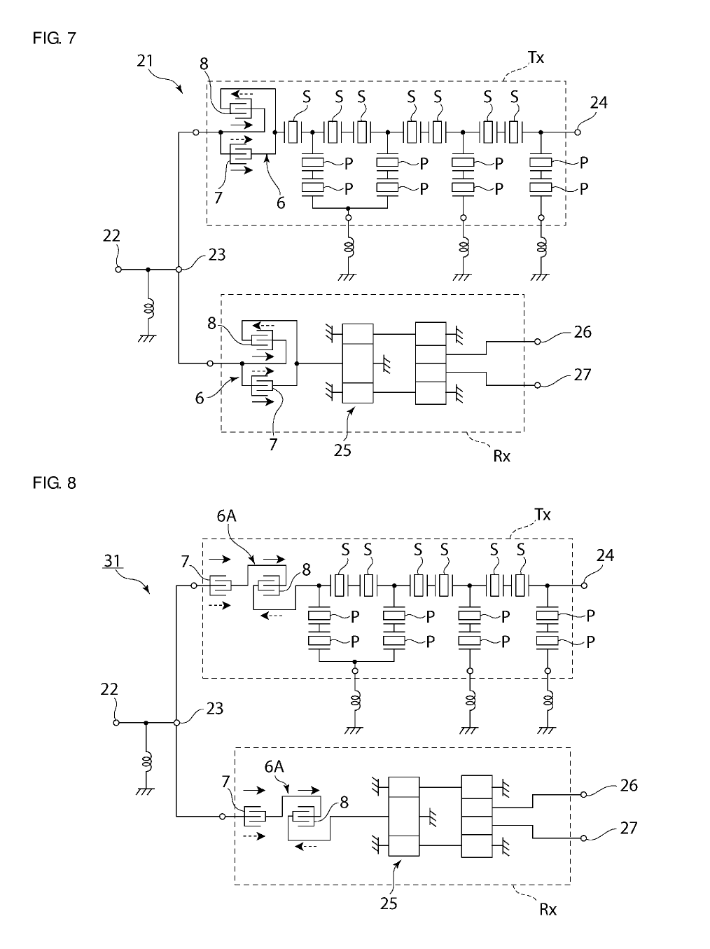

FIG. 7 is a circuit diagram of a duplexer according to a second preferred embodiment of the present invention. The duplexer 21 includes an antenna terminal 22. A transmission filter Tx and a reception filter Rx are connected to a common connection terminal 23 that is a combined end connected to the antenna terminal 22.

The transmission filter Tx includes a ladder filter section. The ladder filter section includes a series arm including a plurality of series arm resonators S. Furthermore, parallel arm resonators P and P are disposed in association with each of first to fourth parallel arms. One end of the ladder filter section is connected to a transmission terminal 24 that defines and functions as an input terminal.

The other end of the ladder filter section is connected to the common connection terminal 23 through a reverse connection portion 6. Thus, the transmission filter Tx includes the above-described ladder filter section and the reverse connection portion 6. As in the first preferred embodiment, the reverse connection portion 6 is arranged on the output terminal side, i.e., on the side opposite to the transmission terminal 24. Accordingly, the generation of the second harmonic distortion signal in the transmission filter Tx is suppressed effectively.

In FIG. 7 and FIGS. 8 to 14 and 17 described later, the projected c-axis is denoted by a solid line, and the direction of the applied electric field in the IDT is denoted by a dotted line.

The series arm resonators S and the parallel arm resonators P are each defined by providing IDT electrodes on a piezoelectric substrate as in the surface acoustic wave filter device 1 illustrated in FIG. 1. In other words, the series arm resonators S and the parallel arm resonators P are each defined by a surface acoustic wave resonator. In third to sixth preferred embodiments described later, series arm resonators S and parallel arm resonators P in a ladder filter section are also defined in a similar manner.

The reception filter Rx is connected between the common connection terminal 23 and first and second reception terminals 26 and 27. In other words, the reception filter Rx includes a balanced surface acoustic wave filter section 25 of longitudinally coupled resonator type, and a reverse connection portion 6. Here, the reverse connection portion 6 is connected to the input terminal side of the surface acoustic wave filter section 25 of longitudinally coupled resonator type, i.e., to the side closer to the common connection terminal 23. In the reception filter Rx, the second harmonic distortion signal is more likely to generate on the input terminal side. In this preferred embodiment, since the reverse connection portion 6 is disposed on the input terminal side, it is also possible to more effectively suppress the second harmonic distortion signal in the reception filter Rx as well.

FIG. 8 is a circuit diagram of a duplexer according to a third preferred embodiment of the present invention. In the duplexer 31 of the third preferred embodiment, reverse connection portions 6A and 6A are disposed respectively in the transmission filter Tx and the reception filter Rx. In other words, the duplexer 31 uses the reverse connection portions 6A and 6A of serially connected type instead of the reverse connection portions 6 and 6 illustrated in FIG. 7. The other configuration of the duplexer 31 is similar to that in the duplexer 21. Therefore, the same components are denoted by the same reference signs, and description of those components is omitted.

Thus, the reverse connection portions 6A and 6A of serially connected type may be used as in the duplexer 31. With the presence of the reverse connection portions 6A and 6A of serially connected type, the generation of the second harmonic distortion signals in the transmission filter Tx and the reception filter Rx is suppressed effectively as in the case of the duplexer 21.

Furthermore, in the case using the reverse connection portion 6A of serially connected type, the electric power handling capability is increased in comparison with that in the first preferred embodiment.

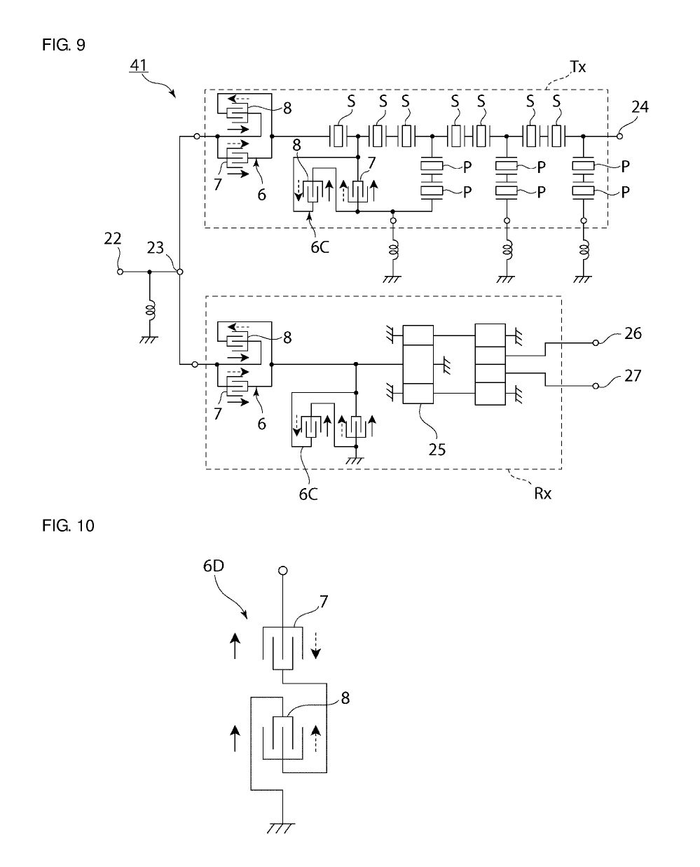

FIG. 9 is a circuit diagram of a duplexer 41 according to a fourth preferred embodiment of the present invention. In the duplexer 41, reverse connection portions 6C and 6C are additionally connected to the duplexer 21 illustrated in FIG. 7.

In more detail, the reverse connection portion 6C is connected instead of the parallel arm resonators P and P in a first parallel arm that is positioned closest to the common connection terminal 23 of the transmission filter Tx in FIG. 7. The reverse connection portion 6C has the same configuration as that of the reverse connection portion 6. In the reception filter Rx, the reverse connection portion 6C is connected between an end of the reverse connection portion 6 on the side closer to the reception terminal and a ground potential.

As described above, the reverse connection portion 6C may be provided between a signal path and the ground potential. In such a case, the second harmonic distortion signal generated in the parallel arm is suppressed. Hence the generation of the second harmonic distortion signal is suppressed effectively in both the series arm and the parallel arm.

While, in the duplexer 41, the reverse connection portions 6C and 6C are each connected between the signal path and the ground potential, a reverse connection portion 6D illustrated in FIG. 10 may be used instead of the reverse connection portion 6C. Stated in another way, as illustrated in FIG. 10, the reverse connection portion 6D of serially connected type may be used instead of the reverse connection portion 6C of parallel connected type.

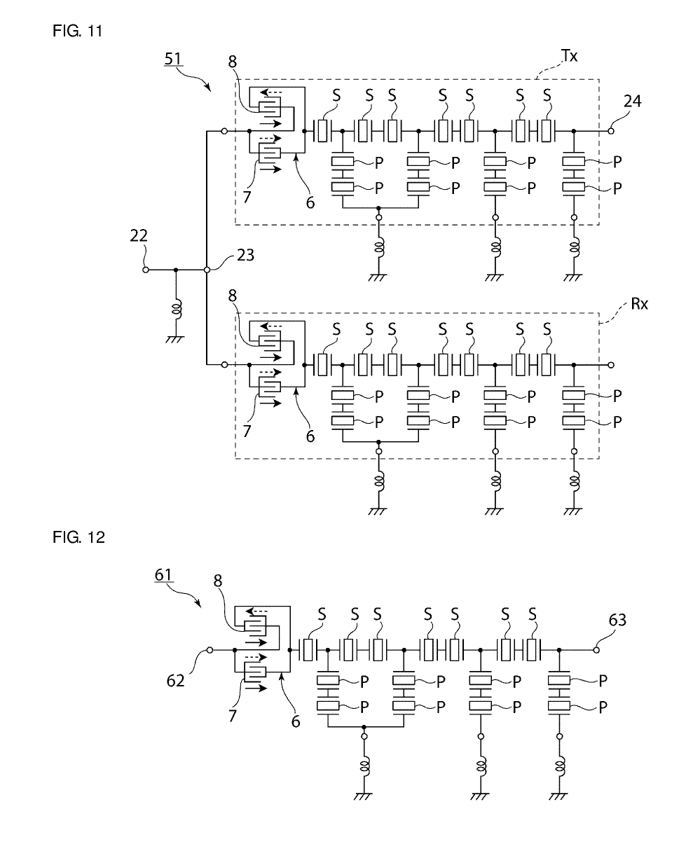

FIG. 11 is a circuit diagram of a duplexer according to a fifth preferred embodiment of the present invention. The duplexer 51 is defined similarly to the duplexer 21 of the second preferred embodiment except that the reception filter Rx is defined as a ladder filter. In this preferred embodiment, the reception filter Rx is defined as a ladder filter including a plurality of series arm resonators S and a plurality of parallel arm resonators P. The reverse connection portion 6 is provided on the input terminal side of the ladder filter, i.e., on the side closer to the common connection terminal 23. Thus, as in the duplexer 51, the reception filter Rx may be defined by a ladder filter section.

In the duplexer 51 of this preferred embodiment, similarly to the duplexer 41 illustrated in FIG. 9, the reverse connection portion 6C may be used instead of one parallel arm in the transmission filter Tx and the reception filter Rx. Furthermore, the reverse connection portions 6D of serially connected type may be used instead of the reverse connection portion 6C.

In addition, the reverse connection portion 6 disposed in the series arm may be replaced with the reverse connection portion 6A of serially connected type illustrated in FIG. 8. In such a case, the electric power handling capability is further increased.

FIG. 12 is a circuit diagram of a surface acoustic wave filter device according to a sixth preferred embodiment of the present invention. The surface acoustic wave filter device 61 is not a duplexer, and it is a ladder filter including a first terminal 62 and a second terminal 63. A circuit configuration of the surface acoustic wave filter device 61 is similar to that of the transmission filter Tx illustrated in FIG. 7. Therefore, the same components are denoted by the same reference signs, and description of those components is omitted. Also in the surface acoustic wave filter device 61 of this preferred embodiment, the reverse connection portion 6 is connected to a surface acoustic wave filter section that is defined as a ladder filter. As a result, the second harmonic distortion signal is suppressed effectively. In a preferable form, the second harmonic distortion signal is further suppressed effectively by using the first terminal 62 as the output terminal.

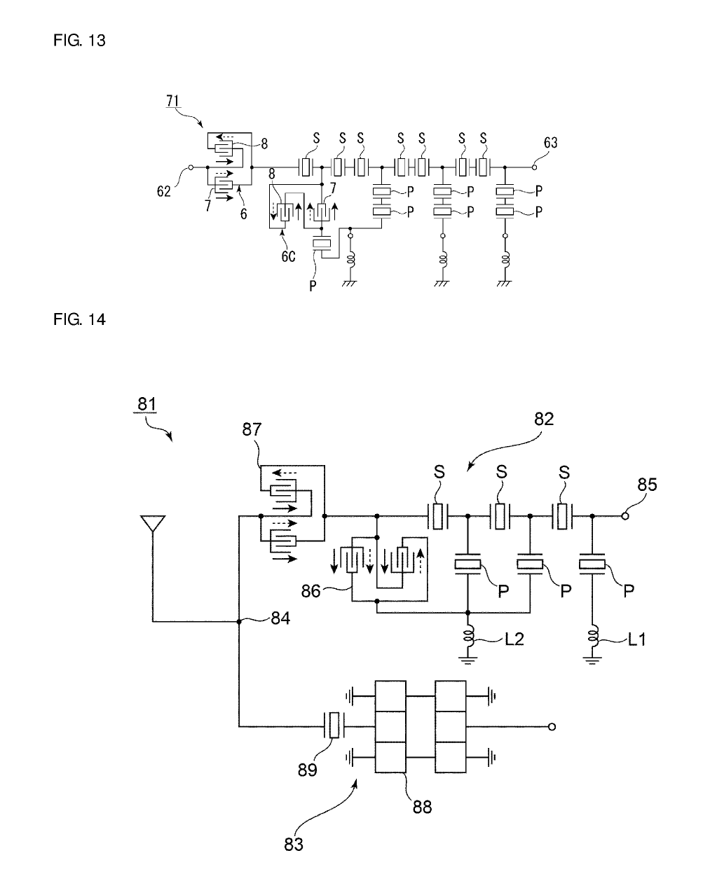

FIG. 13 is a circuit diagram of a surface acoustic wave filter device according to a seventh preferred embodiment of the present invention. In the surface acoustic wave filter device 71, one of the parallel arm resonators P, the one being positioned closest to the first terminal 62 of the surface acoustic wave filter device 61 illustrated in FIG. 12, is replaced with the reverse connection portion 6C. Thus, the reverse connection portion 6C may be disposed as in this preferred embodiment. With the provision of the reverse connection portion 6C, the second harmonic distortion signal in the parallel arm is further suppressed.

FIG. 14 is a circuit diagram of a surface acoustic wave filter device 81 according to an eighth preferred embodiment of the present invention. The surface acoustic wave filter device 81 is a duplexer used in Band 5. The surface acoustic wave filter device 81 includes a transmission filter 82 and a reception filter 83. A pass band, i.e., a transmission band, of the transmission filter is positioned on the lower frequency side than a pass band, i.e., a reception band, of the reception filter.

The transmission filter 82 is defined as a surface acoustic wave filter of ladder type. One end of the transmission filter 82 is connected to an antenna terminal 84. The other end of the transmission filter 82 is connected to a transmission terminal 85. For example, a first terminal is the antenna terminal 84, and a second terminal is the transmission terminal 85.

The transmission filter 82 includes a plurality of series arm resonators S disposed in a series arm. Moreover, a parallel arm resonator P is connected to each of a plurality of parallel arms that are connected between the series arm and a ground potential. An inductance L1 is connected between one of the parallel arm resonators P, the one being positioned closest to the transmission terminal 85, and the ground potential. The remaining parallel arm resonators P and P and an end of a later-described reverse connection portion 86 on the ground potential side are connected in common. An inductance L2 is connected between a junction point, which is connected in common as mentioned above, and the ground potential.

In the series arm, a reverse connection portion 87 formed by dividing one series arm resonator in parallel is disposed on the side closest to the antenna terminal 84. Furthermore, the reverse connection portion 86 is disposed between the common junction point of the reverse connection portion 87 and the series arm resonators S and the inductance L2. The series arm resonators S and the parallel arm resonators P are each defined as a surface acoustic wave resonator. The reverse connection portions 86 and 87 are each formed preferably by dividing one surface acoustic wave resonator into two surface acoustic wave resonators in parallel.

The reception filter 83 includes a surface acoustic wave filter section 88 of a longitudinally coupled acoustic resonator type. A surface acoustic wave resonator 89 is connected between the surface acoustic wave filter section 88 of longitudinally coupled acoustic resonator type and the antenna terminal 84.

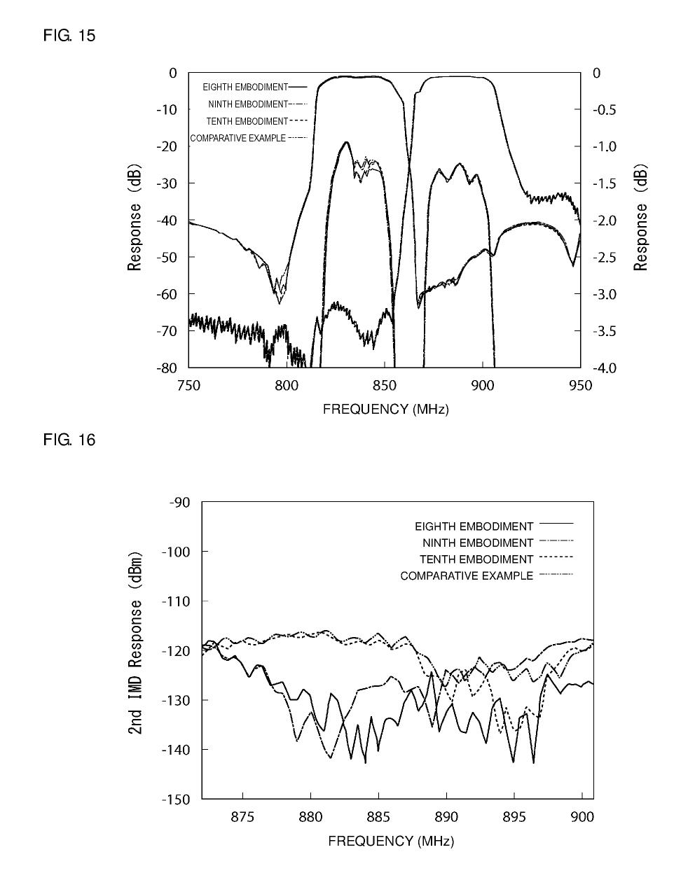

The effect of the surface acoustic wave filter device 81 of the eighth preferred embodiment was compared with those of later-described ninth and tenth preferred embodiments and a comparative example. The obtained results are depicted in FIGS. 15 and 16.

In the ninth preferred embodiment, the reverse connection portion 86 disposed in the parallel arm closest to the antenna terminal 84 in the surface acoustic wave filter device 81 was defined by a surface acoustic wave resonator not divided in parallel. A duplexer of the ninth preferred embodiment was fabricated with the other configuration being the same as that in the above-described eighth preferred embodiment.

The tenth preferred embodiment was defined similarly to the eighth preferred embodiment except for using one surface acoustic wave resonator not divided in parallel instead of the reverse connection portion 87, which was disposed in the series arm and was connected to the antenna terminal 84.

In the comparative example, a duplexer was fabricated similarly to the surface acoustic wave filter device 81 except for replacing each of the reverse connection portions 86 and 87 with a surface acoustic wave resonator not divided in parallel.

FIG. 15 depicts transfer characteristics of the surface acoustic wave filter device 81 of the eighth preferred embodiment, and transfer characteristics in the ninth and tenth preferred embodiments and the comparative example. As seen from FIG. 15, there is not so significant difference in transfer characteristics among the surface acoustic wave filter device 81, the ninth and tenth preferred embodiments, and the comparative example. More specifically, it is understood that, in the surface acoustic wave filter device of the eighth preferred embodiment, an insertion loss in the pass band on the transmission side, i.e., in a higher frequency range within the transmission band, is lower than those in the ninth and tenth preferred embodiments by about 0.1 dB. In comparison with the comparative example, the insertion loss in the higher frequency range within the transmission band is lower by 0.05 dB in the surface acoustic wave filter device 81. Thus, the insertion loss in the surface acoustic wave filter device 81 is substantially equal to that in the comparative example.

FIG. 16 depicts response of second harmonic IMD in a pass band of 875 MHz to 890 MHz, i.e., in the reception band, in the surface acoustic wave filter device 81, the ninth and tenth preferred embodiments, and the comparative example. In comparison with the comparative example, generation of the second harmonic IMD in the above-mentioned band is suppressed in the ninth preferred embodiment. In the tenth preferred embodiment, the response of the second harmonic IMD is reduced in a band of 890 MHz to 900 MHz, i.e., in a higher frequency range within the pass band.

On the other hand, in the surface acoustic wave filter device 81 of the eighth preferred embodiment, the response of the second harmonic IMD is smaller in the band of 875 MHz to 887 MHz and the band of 890 MHz to 900 MHz, i.e., in both the lower frequency range and the higher frequency range within the pass band, than that in the comparative example. Accordingly, in the surface acoustic wave filter device 81 of the eighth preferred embodiment, a nonlinear signal generated due to crystal asymmetry of the piezoelectric substrate is suppressed more effectively than those in the ninth and tenth preferred embodiments and the comparative example.

In a duplexer, a transmitted signal is input to a transmission filter from a transmission terminal. On the other hand, a received signal and noise are mixed into the transmission filter from an antenna terminal. In a transmission filter including a ladder surface acoustic wave filter, a resonant frequency of a parallel arm resonator is positioned near a lower-frequency side end of a pass band in a lower frequency range. Accordingly, near the lower-frequency side end of the pass band, a large amount of electric power is applied to a series arm resonator. Moreover, an anti-resonant frequency of a series arm resonator is positioned near a higher-frequency side end of the pass band in a higher frequency range. Accordingly, near the higher-frequency side end of the pass band, a large amount of electric power is applied to a parallel arm resonator.

When the applied electric power is increased, intermodulation of signals input through the antenna terminal occurs. Therefore, a large nonlinear signal is generated from the series arm resonator in the lower frequency range within the pass band, while a large nonlinear signal is generated from the parallel arm resonator in the higher frequency range within the pass band.

In the surface acoustic wave filter device 81, the reverse connection portion 87 arranged in the series arm and the reverse connection portion 86 arranged in the parallel arm are both disposed on the side close to the antenna terminal 84. Each of the reverse connection portions 86 and 87 has a polarity reversed structure that is obtained by dividing a surface acoustic wave resonator in parallel. It is hence thought that the generation of the second harmonic nonlinear signal is suppressed in both the higher frequency range and the lower frequency range within the pass band. Furthermore, the reverse connection portions 87 and 86 are disposed respectively in the series arm resonator and the parallel arm resonator that are positioned in an edge portion of the filter device on the side closer to the antenna terminal 84 where the second harmonic IMD is more likely to occur, namely that are positioned closest to the antenna terminal 84 to which the transmission filter and the reception filter are connected in common. It is through that, with such an arrangement, the generation of the second harmonic IMD is suppressed effectively over a wide frequency band.

Consequently, as depicted in FIG. 16, in the surface acoustic wave filter device 81, the generation of the second harmonic nonlinear signal is suppressed, without significantly reducing the insertion loss within the pass band of the transmission filter, more effectively over a wide frequency band than in the ninth preferred embodiment using the reverse connection portion 86 disposed only in the parallel arm, the tenth preferred embodiment using the reverse connection portion 86 disposed only in the serial arm, and the comparative example not including any reverse connection portion.

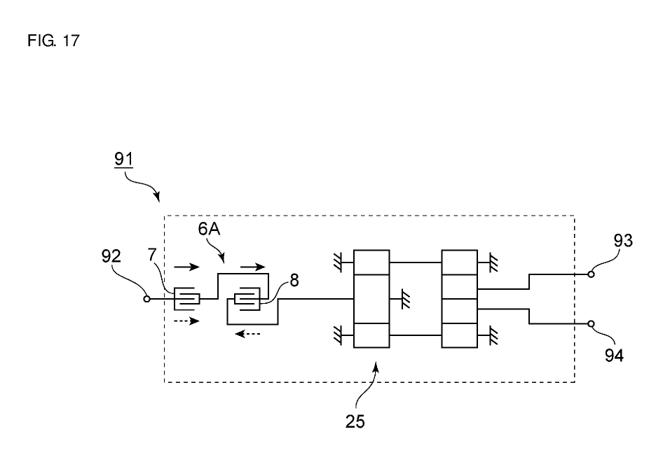

FIG. 17 is a circuit diagram of a surface acoustic wave filter device according to an eleventh preferred embodiment of the present invention. The surface acoustic wave filter device 91 includes an input terminal 92 and balanced output terminals 93 and 94. In the surface acoustic wave filter device 91, the reverse connection portion 6A is connected to the input terminal side of a surface acoustic wave filter section 25 of longitudinally coupled resonator type. Stated in another way, the surface acoustic wave filter device 91 has the same circuit configuration as that of the reception filter Rx of the duplexer 31 illustrated in FIG. 8.

Thus, the reverse connection portion 6A may be connected to the input terminal side of the surface acoustic wave filter section 25 of longitudinally coupled resonator type. As a result, the second harmonic distortion signal is suppressed effectively. Alternatively, the reverse connection portion 6 of parallel connected type may be connected instead of the reverse connection portion 6A.

As is apparent from the preferred embodiments described above, in the surface acoustic wave filter device and the duplexer defined in accordance with the present invention, the reverse connection portion according to various preferred embodiments of the present invention is connected as appropriate to the input terminal side or the output terminal side of the surface acoustic wave filter section. With such an arrangement, the second harmonic distortion signal is suppressed effectively. In that case, the reverse connection portion may be of the serially connected type or the parallel connected type. In a ladder filter, the reverse connection portion may be connected to each of the series arm and the parallel arm. As a result, the second harmonic distortion is suppressed more effectively.

Preferred embodiments of the present invention can be applied to not only a duplexer, but also to other types of multiplexers, such as a triplexer. The resonator except for that in the reverse connection portion may utilize a bulk elastic wave without being limited to a surface acoustic wave.

Moreover, the circuit configuration of the acoustic wave filter section in the acoustic wave filter device according to the present invention is not limited to the ladder type and the longitudinally coupled resonator type.

While preferred embodiments of the present invention have been described above, it is to be understood that variations and modifications will be apparent to those skilled in the art without departing from the scope and spirit of the present invention. The scope of the present invention, therefore, is to be determined solely by the following claims.

What is claimed is:

1. A surface acoustic wave resonator comprising:
a first terminal;
a second terminal;
first and second IDTs connected between the first terminal and the second terminal;
a piezoelectric substrate including a first principal surface and a second principal surface opposed to the first principal surface, and having a c-axis of which direction is inclined relative to the first principal surface and the second principal surface;
a first IDT electrode located on the first principal surface of the piezoelectric substrate to define the first IDT, the first IDT electrode including first and second comb-shaped electrodes; and
a second IDT electrode located on the first principal surface of the piezoelectric substrate to define the second IDT, the second IDT electrode including third and fourth comb-shaped electrodes; wherein
when looking at the first principal surface of the piezoelectric substrate in a plan view, a direction of an electric field applied to the first IDT and a direction of an electric field applied to the second IDT are opposite to each other with respect to a direction parallel to a projected c-axis resulting from projecting the c-axis to the first principal surface of the piezoelectric substrate.

2. The surface acoustic wave resonator according to claim 1, wherein each of the first and second IDT electrodes includes a plurality of electrode fingers, and an extending direction of the projected c-axis resulting from projecting the c-axis to the first principal surface includes a component parallel to a direction in which the plural electrode fingers of the first and second IDT electrodes extend.

3. The surface acoustic wave resonator according to claim 2, wherein, when the c-axis is projected to the first principal surface, the extending direction of the projected c-axis is parallel to the direction in which the electrode fingers of the first and second IDT electrodes extend.

4. The surface acoustic wave resonator according to claim 1, wherein the first IDT and the second IDT are electrically connected in parallel.

5. The surface acoustic wave resonator according to claim 1, wherein the first IDT and the second IDT are electrically connected in series.

6. The surface acoustic wave resonator according to claim 1, further comprising a wiring pattern that electrically connects the first IDT and the second IDT, the wiring pattern being disposed on the first principal surface of the piezoelectric substrate at a position effective to suppress acoustic coupling between surface acoustic waves generated from the first IDT and the second IDT.

7. The surface acoustic wave resonator according to claim 1, further comprising a wiring pattern that electrically connects the first IDT and the second IDT, the wiring pattern being disposed on the first principal surface of the piezoelectric substrate between the first IDT and the second IDT.

8. The surface acoustic wave resonator according to claim 1, wherein the first IDT and the second IDT are spaced from each other in a direction of an electrode-finger intersecting width of the first IDT.

9. A surface acoustic wave filter device including a surface acoustic wave filter section that includes a reverse connection circuit including the surface acoustic wave resonator according to claim 1.

10. The surface acoustic wave filter device according to claim 9, wherein the surface acoustic wave filter section includes a ladder filter section.

11. The surface acoustic wave filter device according to claim 10, wherein
the surface acoustic wave filter device includes an antenna terminal and a transmission terminal;
the ladder filter section includes a series arm connecting the antenna terminal to the transmission terminal, and at least two parallel arms connected to the series arm and a ground potential;
the ladder filter section further includes a plurality of series arm resonators disposed in the series arm, and at least one parallel arm resonator disposed for each of the parallel arms;
one of the plural series arm resonators located closest to the antenna terminal is defined by one unit of the reverse connection circuit; and
the parallel arm resonator arranged in one of the at least two parallel arms located closest to the antenna terminal is defined by another unit of the reverse connection circuit.

12. The surface acoustic wave filter device according to claim 9, wherein the surface acoustic wave filter section includes a surface acoustic wave filter section of a longitudinally coupled resonator type.

13. A multiplexer comprising a common connection terminal and a plurality of filters connected to the common connection terminal in parallel, wherein at least one of the plural filters is defined by the surface acoustic wave filter device according to claim 9.

14. The surface acoustic wave filter device according to claim 9, wherein each of the first and second IDT electrodes includes a plurality of electrode fingers, and an extending direction of the projected c-axis resulting from projecting the c-axis to the first principal surface includes a component parallel to a direction in which the plural electrode fingers of the first and second IDT electrodes extend.

15. The surface acoustic wave filter device according to claim 14, wherein, when the c-axis is projected to the first principal surface, the extending direction of the projected c-axis is parallel to the direction in which the electrode fingers of the first and second IDT electrodes extend.

16. The surface acoustic wave filter device according to claim 9, wherein the first IDT and the second IDT are electrically connected in parallel.

17. The surface acoustic wave filter device according to claim 9, wherein the first IDT and the second IDT are electrically connected in series.

18. The surface acoustic wave filter device according to claim 9, further comprising a wiring pattern that electrically connects the first IDT and the second IDT, the wiring pattern being disposed on the first principal surface of the piezoelectric substrate at a position effective to suppress acoustic coupling between surface acoustic waves generated from the first IDT and the second IDT.

19. The surface acoustic wave filter device according to claim 9, further comprising a wiring pattern that electrically connects the first IDT and the second IDT, the wiring pattern being disposed on the first principal surface of the piezoelectric substrate between the first IDT and the second IDT.

20. The surface acoustic wave filter device according to claim 9, wherein the first IDT and the second IDT are spaced from each other in a direction of an electrode-finger intersecting width of the first IDT.
